(19) United States
(12) Patent Application Publication
(10) Pub. No.: US 2013/0298985 A1
(43) Pub. Date: Nov. 14, 2013

(54) MICROELECTRONIC STRUCTURES INCLUDING CUPROUS OXIDE SEMICONDUCTORS AND HAVING IMPROVED P-N HETEROJUNCTIONS

(71) Applicants: Davis S. Darvish, Santa Monica, CA (US); Harry A. Atwater, South Pasadena, CA (US)

(72) Inventors: Davis S. Darvish, Santa Monica, CA (US); Harry A. Atwater, South Pasadena, CA (US)

(73) Assignee: California Institute of Technology, Pasadena, CA (US)

(21) Appl. No.: 13/876,652

(22) PCT Filed: Sep. 29, 2011
(86) PCT No.: PCT/US2011/053814

§ 371 Date: Jul. 29, 2013

Related U.S. Application Data
(60) Provisional application No. 61/388,047, filed on Sep. 30, 2010.

(51) Int. Cl. H01L 21/02; H01L 31/0336; H01L 29/24

(52) U.S. Cl. CPC H01L 21/02565; H01L 29/242; H01L 31/03365
USPC 136/256; 438/104; 257/43

(57) ABSTRACT

The present invention provides strategies for making higher quality p-n heterojunctions that incorporate cuprous oxide and another material suitable for forming the heterojunction. When incorporated into microelectronic devices, these improved heterojunctions would be expected to provide improved microelectronic properties such as improved defect density, in particular lower interfacial defect density at the p-n heterojunction, leading to improved microelectronic devices such as solar cell devices with improved open circuit voltage, fill factor, efficiency, current density, and the like.

### PRIORITY

The present nonprovisional patent application claims priority under 35 U.S.C.§119(e) from U.S. Provisional patent application having Ser. No. 61/388,047, filed on Sep. 30, 2010, by Darvish et al, and titled MICROELECTRONIC STRUCTURES INCLUDING CUPROUS OXIDE SEMICONDUCTORS AND HAVING IMPROVED P-N HETEROJUNCTIONS, wherein the entirety of said provisional patent application is incorporated herein by reference.

### FIELD OF THE INVENTION

The present invention relates to microelectronic structures incorporating cuprous oxide semiconductor compositions. More particularly, the present invention relates to such structures in which improved p-n heterojunctions are formed at the interfaces between such cuprous oxide semiconductors and adjacent semiconductor regions having oriented crystalline structures.

### BACKGROUND OF THE INVENTION

Cuprous Oxide (often referred to as Cu₂O, although the skilled artisan will appreciate that deviations from this ideal stoichiometry may occur as the result of vacancies, doping, etc.) was the first semiconductor material discovered. Nearly 90 years after its discovery, interest in this material has renewed for use in a variety of microelectronic and energy conversion devices, including thin film photo detectors, photovoltaic devices, diluted magnetic semiconductors, rectifier diodes, optical modulators, particularly for optical fiber communications and the like. Cu₂O has a direct band gap of 2.17 eV and high absorption coefficient in the visible region, rendering this compound suitable for use in solar cells, especially in single junction or multijunction photovoltaic cells or for photo-electrolysis of water. Cu₂O also has long minority carrier diffusion length (˜10 μm). Further, Cu₂O is a relatively non-toxic semiconductor that is composed of both earth abundant and inexpensive elements. This makes terawatt scalability quite feasible, especially if photovoltaic devices incorporating Cu₂O were to play a large role in the energy shift from fossil fuels to solar cells.

Cuprous oxide is typically a p-type semiconductor, with p-type conductivity attributed to copper vacancies in the Cu₂O lattice. Photovoltaic devices incorporating Cu₂O most commonly use Schottky barriers or semiconductor heterojunctions as a means for charge carrier separation.

There are many reports describing Cu₂O solar cells that incorporate semiconductor heterojunctions. These cells have been prepared by various techniques including electro-deposition, thermal oxidation of sheet metal, and sputtering deposition. However, these cells have only reached energy efficiencies that are a fraction of the Shockley-Queisser theoretical value. Notwithstanding the efforts of many researchers, p-n heterojunctions have yet to demonstrate good performance in solar cells and other microelectronic devices. Additionally the control of thin film growth and properties has not been well investigated.

Many researchers have attempted to fabricate p-n heterojunctions from p-type Cu₂O and n-type zinc oxide. The quality of the p-n interface in such devices has been poor. The lack of high quality heterojunction interfaces between Cu₂O and ZnO has resulted in photovoltaic devices with low V_{OC} and fill factor. The quality issue also has resulted only in a record efficiency of about 2%.

Accordingly, the industry still has a strong need to fabricate higher quality p-n heterojunctions that incorporate cuprous oxide and another material suitable for forming the heterojunction.

### SUMMARY OF THE INVENTION

The present invention provides strategies for making higher quality p-n heterojunctions that incorporate cuprous oxide and another material suitable for forming the heterojunction. When incorporated into microelectronic devices, these improved heterojunctions would be expected to provide improved microelectronic properties such as improved defect density, in particular lower interfacial defect density at the p-n heterojunction, leading to improved microelectronic devices such as solar cell devices with improved open circuit voltage, fill factor, efficiency, current density, and the like.

The present invention is based at least in part upon the appreciation that improved n-type emitter material can be grown on underlying surfaces when (1) the underlying surface has an appropriate crystallographic orientation; and (2) the growth of the n-type emitter and optionally the underlying semiconductor region occurs in the presence of a plasma. Surprisingly, plasma-assisted growth helps the emitter material grow on the underlying textured surface with a crystal structure and orientation that is not only much more closely matched to the underlying surface but that is also much different than the crystal structure that more conventionally results when (1) the underlying surface is not appropriately textured in terms of crystalline characteristics and (2) growth occurs in the absence of a plasma. ZnO material, for example, in the absence of a plasma tends to grow on monocrystalline, epitaxial and/or biaxially textured cuprous oxide in phase(s) that are amorphous and/or polycrystalline with a predominant c-plane structure. The poor crystalline orientation of the ZnO results even though the cuprous oxide surface is highly oriented. Yet, if growth of the ZnO occurs at least partially in the presence of a plasma under otherwise substantially identical conditions, then the resultant ZnO film is highly oriented and monocrystalline with an epitaxial and/or biaxially oriented, m-plane structure. Similar effects are observed if the ZnO is grown on a suitable template surface, such as biaxially oriented MgO.

In one aspect, the present invention relates to a method of making a microelectronic structure, comprising the steps of:
a) providing a support, wherein at least a portion of the support comprises a template region having a face;
b) forming an oriented p-type cuprous oxide semiconductor region on the template face;
c) in the presence of a plasma, forming an oriented n-type emitter region on the p-type semiconductor region.

In another aspect, the present invention relates to a method of making a microelectronic structure, comprising the steps of:
a) providing a support, wherein at least a portion of the support comprises a template region having a biaxially oriented crystalline structure, said template region having a face;
b) forming an oriented p-type semiconductor region on the face of the template region, wherein the p-type semiconductor region comprises constituents including at least Cu(I) and oxygen;
c) in the presence of a plasma, forming an n-type emitter region on the p-type semiconductor region, wherein the n-type emitter region incorporates constituents comprising at least Zn and oxygen.

In another aspect, the present invention relates to a method of making a microelectronic structure, comprising the steps of:
a) providing a support, wherein at least a portion of the support comprises a biaxially oriented template region having a face;
b) in the presence of a plasma, forming an oriented n-type emitter region on the template face; and
c) forming a p-type cuprous oxide semiconductor region on the n-type emitter region.

In another aspect, the present invention relates to a method of making a microelectronic structure, comprising the steps of:
a) providing a support, wherein at least a portion of the support comprises a template region having a biaxially oriented crystalline structure, said template region having a face;
b) in the presence of a plasma, forming an n-type emitter region on the face of the template region, wherein the n-type emitter region incorporates constituents comprising at least Zn and oxygen; and
c) forming an oriented p-type semiconductor region on the n-type emitter region, wherein the p-type semiconductor region comprises constituents including at least Cu(I) and oxygen;

In another aspect, the present invention relates to a microelectronic device or precursor thereof incorporating a microelectronic structure made according to any method as described herein.

In another aspect, the present invention relates to a microelectronic device or precursor thereof comprising,
a) an oriented p-type cuprous oxide semiconductor region;
b) an oriented n-type emitter region adjacent to the p-type cuprous oxide semiconductor region in a manner such that a p-n heterojunction is formed between the p-type and n-type regions; and
c) a region adjacent to at least one of the n-type and p-type regions, wherein at least a portion of the region has a biaxially oriented crystalline structure.

In another aspect, the present invention relates to a microelectronic device or precursor thereof comprising,
a) an oriented p-type cuprous oxide semiconductor region;
b) an oriented n-type emitter region adjacent to the p-type cuprous oxide semiconductor region in a manner such that a p-n heterojunction is formed between the p-type and n-type regions, said n-type region incorporating constituents comprising at least Zn and oxygen; and
c) a region adjacent to at least one of the n-type and p-type regions, wherein at least a portion of the template region has a biaxial crystalline structure and wherein the template region comprises constituents including at least Mg and oxygen.

In another aspect, the present invention relates to a photovoltaically active device or precursor thereof comprising,
a) a first oriented semiconductor region comprising constituents of at least Cu(I) and oxygen;
b) a second oriented semiconductor region adjacent to the first oriented semiconductor region such that a p-n heterojunction is formed between the first and second semiconductor regions.
c) a region adjacent to at least one of the first or second semiconductor regions, wherein at least a portion of the template region has a biaxially oriented crystalline structure.

In another aspect, the present invention relates to a photovoltaic device, comprising:
a) a first electrode comprising a biaxially oriented, face centered cubic crystal structure and a first lattice constant associated with a preferentially ordered crystalline characteristic of the first electrode;
b) a p-type cuprous oxide semiconductor region fowled on the first electrode and having face centered cubic crystal structure and a second lattice constant associated with a preferentially ordered crystalline characteristic of the semiconductor region, wherein the ratio of the first lattice constant to the second lattice constant is in the range from about 1:1.05 to about 1.05:1;
c) an n-type emitter region adjacent the p-type cuprous oxide semiconductor region and having face centered cubic crystal structure and a third lattice constant associated with a preferentially ordered crystalline characteristic of at least a portion of the n-type emitter region, wherein the ratio of the second lattice constant to the third lattice constant is in the range from about 1:1.05 to about 1.05:1; and
d) a second transparent electrode formed directly or indirectly on the n-type emitter region.

### BRIEF DESCRIPTION OF THE DRAWINGS

The above mentioned and other advantages of the present invention, and the manner of attaining them, will become more apparent and the invention itself will be better understood by reference to the following description of the embodiments of the invention taken in conjunction with the accompanying drawings, wherein:

FIG. 1 is a schematic diagram of an illustrative microelectronic structure that incorporates a p-n heterojunction of the present invention;

FIG. 2 is a schematic diagram showing an alternative embodiment of a microelectronic structure that incorporates a p-n heterojunction of the present invention; and

FIG. 3 is a schematic diagram illustrating a photovoltaic device that incorporates a p-n heterojunction of the present invention.

### DETAILED DESCRIPTION OF PRESENTLY PREFERRED EMBODIMENTS

The embodiments of the present invention described below are not intended to be exhaustive or to limit the invention to the precise forms disclosed in the following detailed description. Rather the embodiments are chosen and described so that others skilled in the art may appreciate and understand the principles and practices of the present invention. All patents, pending patent applications, published patent applications, and technical articles cited herein are incorporated herein by reference in their respective entireties for all purposes.

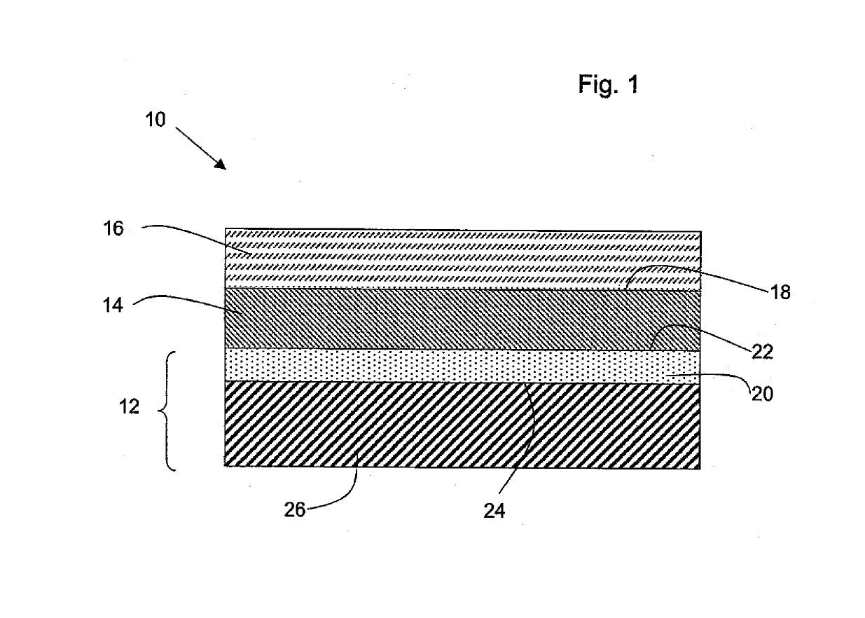

FIG. 1 shows an exemplary microelectronic structure 10 of the present invention incorporating a p-n heterojunction. Structure 10 generally includes substrate 12, cuprous oxide semiconductor region 14, and n-type emitter region 16. The heterojunction is formed at least in part by the interface 18 between the p-type and n-type materials.

Substrate 12 generally provides a stable, smooth, mechanical support on which the other layers of structure 10 may be formed. Additionally, at least a portion of the substrate 12 comprises a template region 20 having a face 22. With respect to the embodiment shown in FIG. 1, template region 20 has characteristics, such as crystalline orientation characteristics, that facilitate growth of successive layers having the same or similar crystallographic orientation on the face 22 of the template region 20. In a preferred embodiment, the template region provides a crystallographic template to facilitate the growth of cuprous oxide semiconductor region 14 having a preferred biaxial orientation. In some cases, additional layers may be provided between the template region and the cuprous oxide semiconductor region 14 in order to obtain a preferred crystallographic orientation of the cuprous oxide semiconductor region 14. The additional layers or regions may be referred to as buffer layers or regions.

Desirably, the template region 20 has crystalline characteristics effective to facilitate crystallographically oriented growth, preferably epitaxial and/or biaxially oriented growth, of the cuprous oxide material grown on the template face 22. As used herein, the terms “oriented” or “textured” can be used interchangeably, and each means that crystalline grains in a region of interest are at least substantially aligned along at least one crystallographic direction. The terms generally refer to a region of interest (e.g., the crystallographic texture proximal to the p-n interface) and need not refer to the crystallographic orientation for the entire film. If crystallographic orientations are substantially completely random, the sample would have no texture. In actual practice, even so-called randomly oriented materials have a modicum of anistropy indicative of a minor degree of orientation. Accordingly, a material is considered to be oriented or textured in the practice of the present invention when the symmetric θ/2θ diffraction patterns obtained using X-ray diffraction (XRD) for that material shows an enhancement of certain Bragg reflections Lₕₖₗ and a reduction of other reflections when compared with the powder pattern of randomly oriented grains of the same material.

In preferred embodiments, at least about 50%, more preferably at least about 60%, more preferably at least about 75%, and even more preferably at least about 90% of the crystal grains in a region of interest are aligned along at least one crystallographic direction, more preferably along at least two crystallographic directions. In some embodiments the region of interest may be an entire film layer, such as when the amount of orientation of crystal grains is substantially constant or generally increasing with film depth in a direction away from an interface of interest between the film and another material that serves as a template for the film or that is templated by the film. In other embodiments the region of interest may be only a portion of a film layer, such as when only a portion of the film proximal to such an interface of interest is at least 50% oriented while regions distal from the interface are oriented to a lesser degree and/or the amount of orientation otherwise decreases with film depth in a direction away from the interface of interest. In these latter embodiments the region of interest is deemed to be the portion of the film to a depth of up to about 100 nm, preferably up to about 50 nm, more preferably up to about 25 nm, even more preferably up to about about 5 nm that is proximal to such interface.

In order to provide a quantitative measurement of the level of orientation or texturing in a thin film sample, the procedures described in Chapter 5 of Birkholz, M. (2006) Texture and Preferred Orientation, in Thin Film Analysis by X-Ray Scattering, Wiley-VCH Verlag GmbH & Co. KGaA, Weinheim, FRG. doi: 10.1002/3527607595.ch5 are used in the practice of the present invention. It will be appreciated by those skilled in the art that supporting analytical characterization may be further provided by selected area diffraction using transmission electron micrscopy (TEM) or reflection high energy electron diffraction (RHEED). In order to demonstrate epitaxial or oriented growth of a thin film during fabrication of a sample, in situ RHEED can be used to monitor texture formation in real time using established methods.

Generally, the degree of orientation typically increases with thickness so long as growth conditions are substantially constant. However, if one changes growth conditions to add additional non-oriented material, then this additional layer would be an additional layer in the structure, even if the transition between layers is gradual. In a case where the degree of texturing indeed decreases with the film depth, and the material is of the same stoichiometry, one could use X-ray methods to determine the texture inhomogeneity within the film according to techniques described in J. T. Bonarski, Progress in Materials Science (2006) 61-149 (See e.g., Section 2.2: methods of inhomogeneity evaluation).

In a uniaxially oriented material, one crystalline axis on the surface and/or within the material is preferentially oriented in a direction along one of the orthogonal directions (e.g., such as being oriented perpendicular to the plane of the surface of the material), while the other two crystalline axes are randomly oriented. The term “biaxially oriented” or “biaxially textured” refers to a material in which crystal grains on the surface and/or within the material are preferentially aligned in two of the orthogonal directions (such as in the out-of plane direction and the in-plane direction), while the remaining axis is randomly oriented.

The term “epitaxial” or “epitaxially formed” refers to a crystallographic structure (or region thereof) in which the preferentially ordered texture in the region of interest is defined or caused at least in part by the ordered texture, e.g., such as the uniaxial or biaxial texture, of an underlying layer. The underlying layer may be referred to as a template layer at least because the template layer functions to reproduce the crystallographic structure of the template layer in material formed on the template layer. An “epitaxial material” or “epitaxially formed” material as described herein may be formed by any mechanism wherein an epitaxial structure is formed in such a templated fashion.

A variety of strategies may be used to provide template region with characteristics suitable to promote oriented growth of the cuprous oxide material. According to one strategy, at least a portion of the template region 20 has a biaxially oriented crystal structure proximal to face 22 to facilitate oriented growth of the cuprous oxide. In another strategy, the crystalline structure of the template is sufficiently lattice-matched with the cuprous oxide material so as to facilitate oriented growth of region 14. Combinations of these strategies also may be used to provide region 20 with the desired template functionality.

FIG. 1 shows an embodiment in which template region 20 forms a portion of substrate 12 that is proximal to the cuprous oxide semiconductor region 14. In such embodiments, template region 20 is formed on an underlying support 26. Support 26 may be rigid or flexible and may be formed from a wide range of materials in one or more layers. Support 26 may be a monocrystalline, polycrystalline or amorphous material. The substrate is preferably substantially physically and chemically inert to the reaction conditions (i.e. temperature, pressure, etc.) under which additional layers such as the template region 20, cuprous oxide semiconductor region 14 and n-type emitter region are formed. Exemplary support materials include semiconductor materials such as Si, Ge, III-V semiconductors such as GaAs, ZnP, and InP, combinations of these, and the like; oxides; nitrides, such as silicon nitride, carbides, or combinations of these; other ceramic materials; polymers; metals, metal alloys, intermetallic compositions, woven or non-woven fabrics, combinations of these, and the like. The support 26 may be formed from one or multiple layers and optionally may incorporate one or more microelectronic devices or precursors thereof. Thus, in some embodiments, the heterojunction is formed on a substrate 12 incorporating all or a portion of one or more underlying devices.

In one exemplary embodiment, support 26 includes a layer of amorphous, polycrystalline, or monocrystalline Si having a protective barrier of thermally grown oxide protecting and isolating the silicon. The template region 20 is grown as a thin film on this support.

Template region 20 can be formed from a variety of one or more materials that have suitable crystalline structures to facilitate oriented growth of the cuprous oxide material. The template region should be closely lattice matched to cuprous oxide in at least one direction. Examples of suitable materials include oxides, nitrides, and/or carbides of one or more metals. Exemplary metals include Mg, Ti, Ta, Zr, Cr and combinations of these. According to one option, preferred oxide, nitride, and/or carbide materials have a face-centered cubic crystal structure with a lattice constant in the range from 0.38 nm to about 0.47 nm, more preferably about 0.41 nm to about 0.44 nm, even more preferably about 0.42 nm to about 0.43 nm. Such materials are generally closely lattice matched to cuprous oxide (a=0.427 nm). According to another option, preferred oxide, nitride, and/or carbide materials have a biaxially oriented texture with crystal grains substantially oriented in plane and out of plane. According to a more preferred option, more preferred oxides, nitrides, and/or carbides have a face centered cubic crystal structure, have a lattice constant according to one or more of the range(s) of parameters recited above, and are biaxially textured. RHEED and X-ray diffraction techniques may be used to assess crystal structure in the practice of the present invention.

In some embodiments, it may be desirable to use one or more template materials that are electrically conductive. In many microelectronic devices, and in particular photovoltaic devices, it is desirable that a conductive layer be formed adjacent to the semiconductor absorber in order to provide a conductive pathway from the semiconductor absorber to external circuitry, thus readily allowing integration with other structure and devices. Examples of template materials of this kind include conductive metal nitrides such as titanium nitride, tantalum nitride, zirconium nitride, titanium carbide, combinations of these, and the like; as well as conductive oxides based on materials such as zinc oxide, cadmium oxide, manganese oxide (MnO), cobaltous oxide combinations of these, and the like. In some embodiments, the conductive template region may be formed on another amorphous or polycrystalline conductive layer or substrate.

MgO is an exemplary material for forming a template region in many modes of practice. As used herein, MgO refers to a material comprising at least one oxide of magnesium wherein at least 90 weight percent, more preferably at least 95 weight percent, and even more preferably substantially all of the metal content of the oxide is magnesium.

MgO is easy to deposit with a biaxially oriented (in plane and out of plane), face-centered cubic crystal structure (001) and has a lattice constant of a=0.422 nm. Thus, MgO and face-centered cuprous oxide (0001) both have a cubic crystal structure and closely matched lattice parameters. There is a lattice mismatch of only about 1.1% between MgO and cuprous oxide. This makes MgO very suitable to promote oriented growth of highly oriented, monocrystalline, preferably epitaxial cuprous oxide (0001) on the MgO. Indeed, cube on cube epitaxy of cuprous oxide (0001) is observed to grow on MgO (001). In situ RHEED analysis was used to confirm epitaxial growth. For example, RHEED oscillations are observed to indicate that the thin film of cuprous oxide is growing on MgO in a layer-by-layer growth regime. This is typically seen if the film growth is well controlled and grown slowly (e.g., on the order of about 2 angstrom/sec in some embodiments). The elongated or ‘streaky’ features along the vertical axis of the RHEED pattern indicate the formation of a relatively smooth or flat surface of the Cu₂O layer. X-ray diffraction analysis confirms the results obtained by RHEED analysis. XRD rocking curve analysis showed epitaxial growth of cuprous oxide on MgO with two peaks at ω=21.58° and ω=21.61°.

Additionally, MgO is transparent, a good insulator, and an excellent mechanical support in bulk form. This makes MgO a useful component in a variety of microelectronic devices in which structure 10 might be incorporated, although all or a portion of the template region optionally may be removed from structure 10 in order to incorporate the heterojunction into a desired microelectronic device.

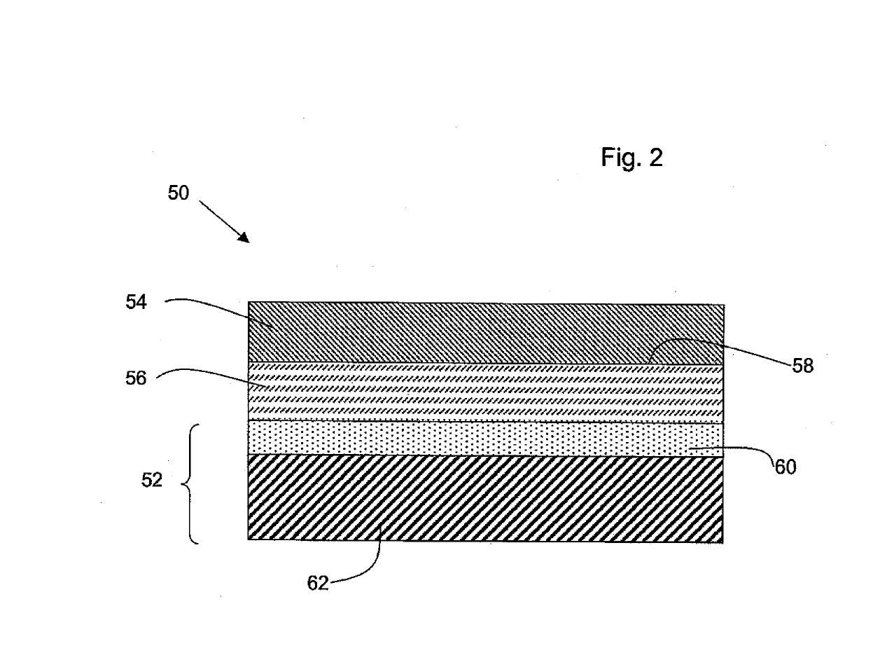

As a further benefit, MgO also is a good template for plasma-assisted growing of oriented, monocrystalline n-type emitter materials such as ZnO as described below in connection with FIG. 2. Thus, MgO can be used as a template for the growth of either crystallographically oriented cuprous oxide or crystallographically oriented n-type emitter material. In exemplary embodiments, the growth of the n-type emitter material onto the template region 22 occurs at least partially in the presence of a plasma in accordance with the present invention.

Although FIG. 1 shows template region 20 as being only a portion of substrate 12, in other embodiments template region 20 may be integrally formed with the bulk of substrate 12. In these embodiments, the bulk of substrate 12 may be formed from material(s) that provide the desired template characteristics at face 22. For instance, suitable bulk MgO can be obtained commercially from sources such as SPI Supplies of West Chester, Pa., MTI Instruments of Albany N.Y., and the Kurt J. Lesker Company of Clairton, Pa.

Whether the template region forms only a portion of substrate 12 or is provided in bulk form, there are a variety of compositional options for providing the template region. As one option, the composition of the template region may be substantially uniform throughout. As another option, because template characteristics are mostly desirable at surface 22, it is not necessary that the entirety of the template region 20 have the characteristics of the surface 22. Regions of template region 20 that are distal from surface 22 need not have template characteristics, if any, to same degree as surface 22. Thus, the composition of the template region may be graded or otherwise non-uniform.

In those embodiments in which template region 20 forms only a portion of substrate 12, the interface 24 between region 20 and the underlying support 26 may be relatively distinct or the transition may be gradual. In some embodiments, the composition may progress in stages in a direction from support 26 to surface 22 such that successive layers or regions transition to become more closely matched to cuprous oxide layer to support oriented, mono crystalline, preferably epitaxial growth of the cuprous oxide.

Providing template region 20 as a thin film according to FIG. 1 is preferred. Using a thin film template region 20 offers many advantages as compared to using bulk template material. As one advantage, the template material tends to be more expensive than other substrate materials. Hence, substantial cost savings can be realized as less template material is used to make thin films. Less expensive materials can then be used for the underlying support. This method also allows the resultant p-n heterojunction to be grown on top of already existing device(s). This expands the range of available design possibilities, including the easy incorporation of these p-n heterojunctions into tandem solar cells. Additional advantages can be realized if the template material can perform an integral function in a microelectronic device, such as a solar cell device. Examples of such functions include the use of conductive template regions that can function as either a back electrical contact or top (transparent) conductive layer within a solar cell device. Additionally, because the template region is relatively thin, the resulting cuprous oxide film (or ZnO film as described below) grown on the template will tend to be less strained and, consequently, of higher quality. Further, the same techniques that are used to deposit monocrystalline cuprous oxide on bulk material can be used to deposit monocrystalline cuprous oxide on thin film template material.

Ion beam assisted deposition (IBAD) or reactive ion beam assisted deposition (RIBAD) is one exemplary technique that may be used to form biaxially textured, thin film template region 20, such as MgO or TiN films. Using such IBAD techniques, it is desirable to grow template region 20 in stages for enhanced quality. Schematically, there are two major stages of growth according to these techniques, wherein the first stage can be further viewed as occurring in three sub-stages, also referred to herein as phases. As an overview, the first stage is to deposit an initial portion of the template region. The initial material has a desired biaxially orientation, but may have significant ion damage. In the second stage, more MgO is deposited in a manner that repairs the ion damage and also develops a template layer with better quality.

The use of IBAD techniques will now be described in the context of templates of MgO thin films that are used to grow epitaxial cuprous oxide, but it is understood that these techniques are applicable to other template material as well. Prior to the actual growth of MgO, the support 26 desirably is cleaned to remove contaminants, such as organic contaminants. A wide variety of cleaning techniques may be used. As one example, plasma cleaning, such as by using RF plasma, would be suitable to remove organic contaminants from metal-containing supports. Other examples of useful cleaning techniques include ion etching, wet chemical bathing, and the like.

Using IBAD techniques, a first phase of MgO deposition occurs in the presence of ion bombardment of the support 26. Ion bombardment occurs at a suitable angle such as 45 degrees from an axis normal to the substrate. Ions of a suitable energy are used. In one embodiment, using 750 eV Ar+ions would be suitable. In conjunction with the ion bombardment of the support 26, the MgO may be deposited using any suitable deposition technique. An exemplary technique is e-beam evaporation.

IBAD growth of MgO can be viewed as a three-phase process. In a first phase, an initial film thickness of MgO is deposited. The initial film is likely amorphous as deposited. In many embodiments, this first film may be formed up to a thickness of 20 nm, preferably up to about 10 nm, more preferably up to about 4 nm. During a second phase of growth, MgO crystals are believed to nucleate via solid phase crystallization with out-of-plane texturing as more film thickness is built up. In a third stage of growth, in-plane texturing is evolved due to the amorphization of grains with misaligned in-plane texturing from the Ar+ions. IBAD growth occurs at least until enough material is deposited, an energetically low surface of (001) is formed. In some embodiments, this occurs when the film thickness is about 8 nm to about 30 nm in thickness. In one embodiment, IBAD growth occurred until the film thickness reached about 10 nm. RHEED analysis can be used to confirm and monitor the growth of biaxially textured MgO.

The IBAD growth of the initial MgO film occurs at a suitable rate that allows the development of the biaxial texture. In one embodiment, growth at a rate of about 0.2 nm/sec would be suitable. The IBAD growth may occur using a wide range of temperatures that are at, below, and/or above ambient room temperature. Room temperature growth is convenient and suitable. In a particular embodiment, a first stage of IBAD growth occurs at a deposition rate of 0.5 nm/s on a substrate at room temperature to grow a film having a thickness of 5 nm.

During a second stage of growth, the ion beam is turned off and epitaxial MgO is deposited to further increase the film thickness and to develop a higher quality, more defect-free template surface. MgO can be deposited using the same and/or different techniques as were used for IBAD growth. It is convenient to use the same deposition technique for both the first IBAD stage and the second epitaxial stage. Desirably, the epitaxial growth occurs at one or more temperatures sufficient to provide the energy needed to allow epitaxial growth. Such growth temperatures can be selected from a wide range including room temperature, below room temperature, or above room temperature. Indeed, the applicable phase diagram for this growth would theoretically allow use of temperatures in excess of 2000° C., although such higher temperatures are not the most practical. Yet, using higher deposition temperatures during epitaxial growth tends to produce a higher quality film. Accordingly, in illustrative modes of practice, carrying out growth at a temperature in the range of 500° C. to 700° C. would be suitable. RHEED analysis may be used to continue to confirm and monitor the growth of the epitaxial MgO film.

The additional epitaxial MgO deposited in the second stage may have a thickness over a wide range. Generally, if the additional epitaxial MgO material is too thin, the desired quality improvement may be realized to a lesser degree. Thicker layers are technically feasible but offer little extra benefit to justify the increase in cost. Balancing such concerns, the additional epitaxial MgO material may have a thickness in the range from about 1 nm to about 500 nm, desirably from about 5 nm to about 100 nm, more preferably from about 7 nm to about 80 nm. In one embodiment, the second stage of growth deposits an additional 10 nm of epitaxial MgO at 0.5 nm/s on a substrate at 650° C.

After the biaxially textured MgO film is formed, it is desirable to anneal the film to achieve the higher quality crystalline material. Annealing desirably occurs at a sufficient temperature for a sufficient time in the presence of oxygen to induce crystallization of amorphous regions and allow diffusion of atoms to other areas of the crystal. Such temperatures can be selected from a wide range including room temperature, below room temperature, or above room temperature. Indeed, the applicable phase diagram for this growth would theoretically allow use of in excess of 2000° C., although such higher temperatures are not the most practical. Yet, using higher deposition temperatures during epitaxial growth tends to produce a higher quality film. Accordingly, in illustrative modes of practice, carrying out growth at a temperature in the range of 500° C. to 700° C. would be suitable. for a time period in the range from about 3 seconds to about 100 hours, more preferably for a time period in the range from about 2 minutes to about 200 minutes. In some embodiments, a suitable oxygen pressure is in the range from about 10⁻⁷ torr to about 10⁻⁴ torr. In one experiment, an oxygen pressure of about 10⁻⁶ torr provided cuprous oxide exhibiting a very sharp RHEED.

Cuprous oxide semiconductor region 14 is formed on substrate 12. As used herein, cuprous oxide refers to any oxide and/or oxyhydride of Cu(I). As an option, region 14 may include one or more other constituents in addition to Cu(I) and oxygen. Examples of other possible constituents include one or more other p-type semiconductors, dopants, lattice substituents, and/or the like. Examples of such lattice constituents include sulfur, selenium, nitrogen and combinations of these. One or more optional dopants also may be incorporated into the semiconductor region. Examples of such dopants include nitrogen, chlorine, copper, lithium, and combinations of these. In addition to lattice constituents and/or dopants, other constituents include aluminum, gallium, and indium, and combinations of these. Cuprous oxide semiconductors also may have lattice vacancies wherein one or more of Cu(I) and/or O are missing at one or more lattice locations and are not replaced by other lattice constituents. In particular, Cu vacancies help contribute to p-type characteristics. However, it is preferred that region 14 includes at least 50 weight percent, preferably at least 75 weight percent, and more preferably at least 90 weight percent, even more preferably at least 95 weight percent cuprous oxide based on the total weight of region 14.

At least a portion and more preferably at least substantially all of the cuprous oxide semiconductor material desirably has a monocrystalline, face-centered cubic crystal structure (0001). Desirably, the crystalline structure is epitaxial and/or biaxially oriented in plane and out of plane as these forms provide higher quality, better electronic performance. By using template region 20 and appropriate growth conditions, the growth and crystal orientation at the atomic layer can be well controlled.

Monocrystalline cuprous oxide (0001) may be formed on the template region 20 in a variety of ways. Techniques that provide more highly oriented cuprous oxide are preferred. More preferred are techniques that form epitaxial and/or biaxially oriented cuprous oxide on the template region.

In an exemplary mode of practice, plasma-assisted molecular beam epitaxy (MBE) is used to grow highly oriented, epitaxial, monocrystalline, p-type cuprous oxide on the template region 20. Plasma-assisted MBE advantageously provides enhanced control over growth conditions including temperature, flux, base pressure, interface quality, and the like. Moreover, forming cuprous oxide in the presence of a plasma advantageously and desirably can provide higher oxygen incorporation into the cuprous oxide films at lower oxygen partial pressures.

The plasma can be generated using different sources, such RF, DC or IC (inductively coupled) sources, and/or the like. In an exemplary embodiment, the plasma is generated using an RF source in the presence of a mixture of oxygen and argon gas. The plasma is defined typically by a power and pressure of oxygen that indicates the amount of oxygen. A wide range of plasma powers and oxygen pressures can be used. The parameters selected will depend upon factors such as the type of equipment being used, the nature of the template, and the nature of the cuprous oxide being grown. In one embodiment, an RF oxygen plasma (P=300 W) at 10⁻⁵ torr and having a beam equivalent pressure of about 5×10⁻⁷ torr would be suitable.

According to the present invention, a plasma containing purified oxygen is more preferred for growing the copper oxide layer as well as the n-type emitter layer described further below. However, other plasmas including oxygen in combination with one or more other plasma constituents also may be used. For example, a plasma can be used that includes an inert gas such as one or more of argon, nitrogen; and/or other reactive species such as ozone, combinations of these, and the like in combination with oxygen.

The Cu may be obtained from variety of different sources. Examples of these include copper containing targets, effusion cells containing Cu, copper shot evaporation sources, combinations of these and the like. In preferred embodiments, a copper effusion cell would be suitable.

The rate of deposition of the cuprous oxide can influence the quality of the resultant film. If the deposition rate is too fast, the deposited material may not have enough time to develop the desired orientation. If too slow, throughput efficiency may be too low. Balancing these concerns, cuprous oxide preferably may be deposited at a rate in the range from about 0.05 nm/s to about 0.5 nm/s. In one embodiment, a deposition rate of about 0.2 nm/s would be suitable.

The formation of the cuprous oxide semiconductor can be carried out over a wide range of temperatures. The formation of this material may occur at one or more temperatures including those below room temperature, at about room temperature (25° C.) and above room temperature ranging up to about 1100° C. The formation more desirably is carried out at a temperature between about 500° C. and about 800° C.

The resultant region 14 may have a range of thicknesses. If the region 14 is too thin, then the cuprous oxide material may not effectively absorb a sufficient amount of light that reaches this layer in a resultant photovoltaic device. Cuprous oxide layers that are too thick would be able to absorb the majority of light entering the layer and provide sufficient photovoltaic functionality, but are wasteful in the sense of using more material than is needed for effective light capture may also suffer from reduced fill factors due to increased series resistance. Balancing these concerns, region 14 desirably has a thickness in the range from about 0.8 μm to about 5 μm, preferably from about 0.8 μm to about 3 μm. In one embodiment, a thickness of 2 μm would be suitable.

In a representative mode of practice, oriented copper oxide is grown at 0.02 nm/s with a substrate temperature of 650° C. to a total thickness of 200 nm using an oxygen partial pressure of 5×10⁻⁵ torr (RF power=250 W).

According to the embodiment of FIG. 1, the n-type emitter region 16 is formed on oriented, monocrystalline cuprous oxide region 14 in the presence of a plasma. A variety of n-type emitter materials can be used singly or in combination to form region 16. Examples of such materials include zinc oxide, cadmium oxide, indium oxide combinations of these, and the like. Zinc oxide is preferred at least because zinc oxide is a wide bandgap semiconductor, zinc oxide is earth abundant, and because of the band offsets between copper oxide and zinc oxide are favorable for high efficiency solar cells.

Oriented cuprous oxide, particularly epitaxial and/or biaxially oriented cuprous oxide (0001), has an appropriate surface that facilitates plasma-assisted, oriented growth of monocrystalline, n-type material. As used herein, the term “oriented” with respect to a crystalline material means that that at least one crystalline axis of the grains a material is preferentially ordered in one of the three orthogonal directions (a, b, c). All or a portion of region 16 is oriented. More preferably, at least a portion of the n-type material is sufficiently oriented so as to be epitaxial and/or have a uniaxially or biaxially oriented texture in plane and out of plane. More preferred n-type materials desirably have an m-plane orientation, e.g., zinc oxide with an m-plane orientation has a (10-10) monocrystalline structure. If only a portion of region 16 is oriented, the oriented region is proximal to region 14 so as to provide a high quality interface between the n-type and p-type materials. Distal portions can be the same or different. For example, an embodiment of region 16 with a graded or layered composition can be formed by initially growing epitaxial and/or biaxially oriented ZnO on region 14. When a desired thickness of this oriented material has been grown, e.g., a film having a thickness in the range from about 5 to about 50 nm, co-deposition of the zinc with one or more other metals, dopants, or the like, can be initiated. For instance, Zn initially can be deposited in the presence of an oxygen plasma by itself to form an oriented zinc oxide. Then co-deposition of zinc with aluminum can be initiated to grow a more conductive aluminum-doped zinc oxide. In this manner, a device structure can be fabricated in which a transparent conductive oxide region (AZO) is adjacent to the oriented p-n heterojunction. For purposes of illustration, FIG. 1 shows an embodiment of region 1 having a uniform composition throughout.

Growing the n-type emitter on an oriented cuprous oxide surface in the presence of a plasma helps the n-type layer to form with more control and with oriented crystalline characteristics that are more closely matched to the underlying semiconductor surface on which the n-type layer is grown. Hence, the quality of the p-n interface is better. The ability to grow n-type emitter material that is more favorably oriented and textured should lead to heterojunctions with improved performance. Both higher Voc and efficiencies should be obtained due to the greater control obtained over the crystal orientation and the higher quality interface.

Without wishing to be bound by any particular theory of operation, it is believed that the improved orientation of the n-type material occurs either as a result of epitaxial growth and/or as a result of in situ conversion to a biaxially oriented, monocrystalline structure as a consequence of the plasma and other reaction conditions. According to the suggested epitaxial mechanism, the plasma allows the n-type material to grow epitaxially on the underlying material even though the n-type material would be too lattice mismatched to grow epitaxially in the absence of the plasma. According to the suggested in situ conversion mechanism, the n-type emitter perhaps might be deposited initially in an amorphous or polycrystalline structure. Exposure to the plasma, though, helps to convert this amorphous and/or polycrystalline structure to a single crystalline, more oriented structure, e.g., a biaxially oriented structure. Also, while not wishing to be bound, it is believed that using plasma allows kinetic growth effects to dominate during film growth rather than equilibrium growth effects.

This is surprising, because in the absence of the plasma, the n-type layer may have a tendency to be deposited in a manner so as to be more mismatched with the cuprous oxide and less oriented. The benefits of using plasma assisted growth of n-type emitter material(s) on an oriented cuprous oxide material are exemplified by the use of zinc oxide. When deposited conventionally in the absence of a plasma, films of zinc oxide tend to be very mismatched with the cuprous oxide in terms of crystalline characteristics. As a consequence, the ZnO tends to be amorphous and/or polycrystalline rather than being monocrystalline with an epitaxial and/or biaxial texture. Yet, in the presence of a plasma, single crystal ZnO readily forms that is highly oriented and more closely lattice matched with the underlying cuprous oxide.

For example, oxygen plasma assisted MBE allowed the growth of ZnO thin films with a preferential (10-10) orientation a very weak peak corresponding to the more commonly observed (0002) orientation that would be expected to be observed if growth occurred in the absence of a plasma. The dominant peak (10-10) is much more closely matched to the epitaxial cuprous oxide (0001) and the biaxially textured MgO (001). Hence, growth in the plasma facilitates a more strongly textured and oriented growth of single crystal ZnO on either the cuprous oxide or, as described further below, on a template surface such as biaxially textured MgO (001). Indeed, the improved structural, optical, and electronic qualities of n-type emitter material deposited in the presence of a plasma were confirmed on bulk MgO and cuprous oxide substrates using RHEED, X-ray diffraction, EDS, spectroscopic ellipsometry, and Hall mobility measurements. Without wishing to be bound, it is believed that there may be some polycrystalline and/or amorphous ZnO phases that grow initially. However, these appear to quickly change and develop into the m-plane texture.

A variety of plasma-assisted techniques may be used to grow oriented n-type emitter material(s) on the cuprous oxide semiconductor region 14. For purposes of illustration, an exemplary mode of practice for growing an oriented ZnO thin film on cuprous oxide semiconductor region 14 will now be described.

Prior to growth of the n-type emitter, it may be desirable, but not necessary, to clean the surface on which the emitter material will be grown. A wide variety of cleaning techniques can be used to accomplish cleaning, including wet and/or dry techniques. Dry techniques are more preferred. According to one dry technique, the surface is thermally cleaned at a suitable temperature for a suitable time period using a plasma, such as an RF oxygen plasma. In one embodiment, thermally cleaning the surface at a temperature of about 450° C. for a time period of about 15 minutes would be suitable.

The n-type emitter layer is then grown on the cleaned surface in the presence of a plasma. A range of different plasmas would be suitable, including RF, DC, IC, combinations of these, and the like. An RF oxygen plasma is preferred.

A wide range of plasma conditions would be suitable. For instance, an exemplary RF oxygen plasma may be used that is generated via a power in the range of about 100 W to about 300 W at a pressure in the range from about 10⁻⁶ torr to about 10⁻⁴ torr and having a beam equivalent pressure in the range of from 10⁻⁶ torr to about 10⁻⁵ torr. In one embodiment An RF oxygen plasma (P=200 W) at 10⁻⁵ torr and having a beam equivalent pressure of about 1×10⁻⁶ ton would be suitable. If the pressure is too high, a desired level of oriented growth may not result. If the pressure is too low, undue amounts of Zn metal may be deposited.

The temperature(s) for growing the n-type emitter material may be within a wide range. If the temperature is too low, then the as-grown film may not be able to adopt a preferred crystalline orientation. If the temperature is too high, then deleterious reactions may occur that affect the desired composition or uniformity of the n-type region and may also cause undesired migration of elements between the n-type and p-type regions. Balancing such concerns, the growth desirable occurs at temperature(s) in the range from about 25° C. to about 600° C., more preferably about 100° C. to about 450° C. In one embodiment, a temperature of about 350° C. would be suitable for growing monocrystalline, oriented n-type emitter material.

The growth rate can impact the growth of the desired oriented n-type material. Generally, if the rate is too fast, a material such as ZnO may tend to grow in a more conventional c-plane (0001) orientation rather than the desired m-plane (10-10) orientation. Slower growths tend to favor the formation of the desired m-plane phase. Very slow growth rates can be used, but will cause throughput efficiency to be reduced. Balancing such concerns, it is desirable to grow the n-type emitter material at a rate in the range from about 0.01 to about 1.0 nm/s. In one embodiment, a growth rate of 0.2 nm/sec would be suitable to grow monocrystalline ZnO having an m-plane orientation. RHEED and X-ray diffraction analysis may be used to monitor and control the growth.

In a representative mode of practice, oriented zinc oxide is grown at 0.02 nm/s with a substrate temperature of 350° C. to a total thickness of 100 nm using an oxygen partial pressure of 8×10⁻⁶ torr (RF power=250 W).

FIG. 2 shows an alternative embodiment of a microelectronic structure 50 of the present invention incorporating a p-n heterojunction. Structure 52 generally includes substrate 52, cuprous oxide semiconductor region 54, and n-type emitter region 56. At least a portion of substrate 52 includes template region 60. The p-n heterojunction is formed at least in part by the interface 58 between the p- and n-type materials. Structure 50 is similar to structure 10 of FIG. 1 except that n-type emitter region 56 is formed on template region 60 in the presence of a plasma, and then semiconductor region 54 is formed on the n-type emitter region 56. The template surface, which preferably is biaxially textured MgO, has an appropriate surface that facilitates plasma-assisted, oriented growth of monocrystalline, n-type material. The same features and growth techniques used with respect to FIG. 1 may be incorporated into and/or used to grow corresponding components of structure 50. All or a portion of substrate 53 may be removed in the course of incorporating the resultant p-n heterojunction into a microelectronic device.

The p-n heterojunctions of the present invention may be used in a wide range of microelectronic devices. Examples include photovoltaic devices (particularly multi junction photovoltaic devices), thin film batteries, liquid crystal displays, light emitting diodes, combinations of these, and the like.

Because the band gap of cuprous oxide is 2.17 eV, this material is well-suited for a top cell in a multi junction photovoltaic device. Such devices preferentially utilize tunnel junctions between the top cell and subsequent cells having lower band gaps. Accordingly, in one embodiment of this invention there is provided a microelectronic device or precursor thereof comprising,
a) an oriented p-type cuprous oxide semiconductor region;
b) an oriented n-type emitter region adjacent to the p-type cuprous oxide semiconductor region in a manner such that a p-n heterojunction is formed between the p-type and n-type regions; and
c) a region adjacent to at least one of the n-type and p-type regions, wherein at least a portion of the region has a biaxially oriented crystalline structure; and a tunnel junction between the cuprous oxide semiconductor device and at least one other photovoltaic device, said other device having a lower band gap than the cuprous oxide device.

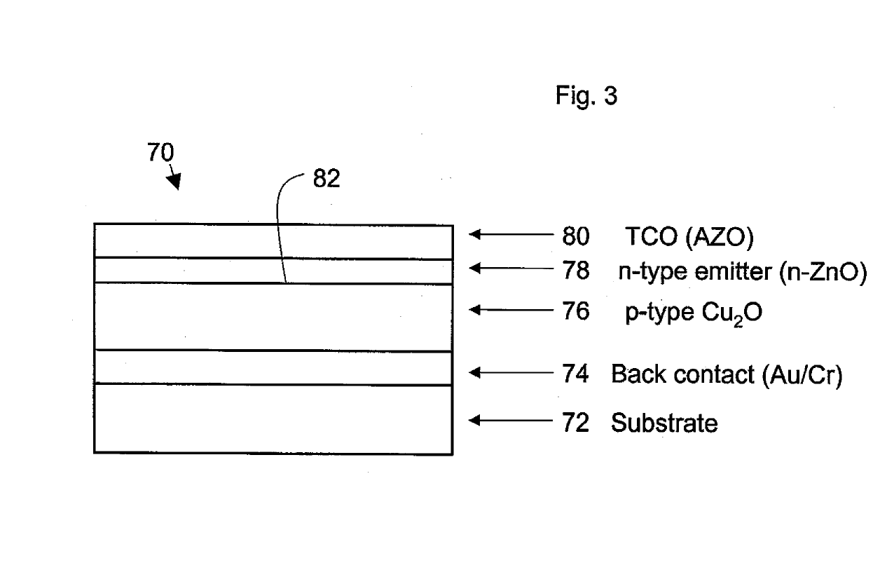

An exemplary photovoltaic device 70 incorporating a p-n heterojunction of the present invention is shown in FIG. 3. A back contact 74 is provided on substrate 72. Contact 74 may include one or more electrically conductive materials. In one embodiment, the back contact 74 may include Au/Cr. Oriented p-type copper oxide layer 76 is formed on contact 74. An oriented n-type emitter layer 78 is formed on the copper oxide layer 76 in templated fashion so that the copper oxide layer 76 serves as a template for the oriented growth of the emitter layer 78. The interface 82 between layer 76 and layer 78 provides a p-n heterojunction. In an exemplary embodiment, emitter layer 78 includes zinc oxide. A transparent conducting oxide layer 80 is formed on the n-type emitter layer 78. In an exemplary embodiment, the layer 80 includes aluminum zinc oxide (AZO).

The present invention will now be described with reference to the following illustrative examples.

### EXAMPLE 1

Cu₂O/ZnO heterojunctions as used in this example are grown. on bulk MgO (100) crystals using plasma-assisted molecular beam epitaxy. An MgO substrate is silver pasted to a substrate chuck and loaded into the MBE. The UHV silver paste is the method of both securing the substrate on the chuck as well as providing superior thermal contact as compared to clipping the substrate down. The substrate is then cleaned in an oxygen plasma (P_{O2}=5×10⁻⁵, P=250 W, T_{sub}=650 C) for 10 minutes before deposition. Following cleaning, epitaxial Cu₂O is deposited on the MgO (P_{O2}=5×10⁻⁵, P=250 W, T_{sub}=650 C, Deposition Rate=0.02 nm/Sec) until a thickness of 0.5 μm is reached. Crystallinity, epitaxy, and growth rate are all monitored thru in-situ RHEED and XRD. These show a fully oriented, single crystalline film that is believed to be oriented out of plane.

The substrate is then allowed to cool to 350° C. prior to the deposition of the ZnO layer. ZnO is deposited on top of the Cu₂O (P_{O2}=5×10⁻⁵, P=250 W, T_{sub}=350 C Deposition Rate=0.04 nm/Sec) until a thickness of 100 nm is reached. The RF Oxygen plasma assists in depositing epitaxial m-plane (10-10) ZnO which is monitored via in-situ RHEED. For confirmation of oriented growth, one should see a RHEED diffraction pattern indicative of a single crystal film. Examples of the way this pattern would look include diffraction “spots” or “streaks”. If diffraction rings are visible (indicative of polycrystalline growth), the intensity of such rings desirably is less than that of the spots or streaks for a material to be satisfactorily textured. More preferably, the intensity of the diffraction rings is 50% or less, more preferably 10% or less of the intensity of the spots or streaks. Further characterization of the structure of the thin films is done via XRD. This characterization yields XRD patterns showing a single peak for each of the MgO, the cuprous oxide, and the zinc oxide, respectively, indicating that each material is single crystalline and fully textured.

### EXAMPLE 2

Solar cell heterojunctions are made in accordance with Example 1 except that the bulk substrate is substituted with an IBAD MgO (100) templated substrate (atomically smooth silicon, quartz, glass, SiN, etc,) produced in two stages as described herein. Characterization of the structure of the thin films is done via XRD. This characterization yields XRD patterns showing a single peak for each of the MgO, the cuprous oxide, and the zinc oxide, respectively, indicating that each material is single crystalline and fully textured.

### EXAMPLE 3

Cu₂O/ZnO heterojunctions can be grown using plasma-assisted molecular beam epitaxy on a TiN (100) template in a similar manner as described for example 1. A textured TiN thin film can be deposited on a substrate using reactive ion beam-assisted deposition (RIBAD) from a pure (99.9999%) Ti target using rf plasma source and an ion beam comprising a mixture of argon and nitrogen (volume ratio 1:1) directed at a 45° angle relative to the substrate.

The overall deposition rate during the RIBAD process can be set to about 0.1nm/s by adjusting the ablation rate of the Ti target. After forming the TiN thin film template, the copper oxide and zinc oxide may be grown as described in Example 1. Characterization of the structure of the thin films may be done via XRD. This characterization would yield XRD patterns showing a single peak for each of the MgO, the cuprous oxide, and the zinc oxide, respectively, indicating that each material is single crystalline and fully textured.

### Comparative Example A

Solar cell heterojunctions are made in accordance with Example 1 except that the growth of ZnO is not conducted in the presence of an oxygen plasma or any other plasma. The resultant layer is a polycrystalline ZnO thin film whose growth can be monitored via in-situ RHEED. One would observe diffraction rings, indicative of polycrystalline growth.

Other embodiments of this invention will be apparent to those skilled in the art upon consideration of this specification or from practice of the invention disclosed herein. Various omissions, modifications, and changes to the principles and embodiments described herein may be made by one skilled in the art without departing from the true scope and spirit of the invention which is indicated by the following claims. Each patent, published patent application, technical article, and any other publication referred to herein is incorporated herein by reference in its respective entirety for all purposes.

1. A method, comprising the steps of:
a) providing a support, wherein at least a portion of the support comprises a template region having a face;
b) forming an oriented p-type semiconductor region on the template face, wherein the p-type semiconductor region comprises constituents including at least Cu(I) and oxygen;
c) in the presence of a plasma, forming an oriented n-type emitter region on the p-type semiconductor region.

2. The method of claim 1, wherein the template region includes a face centered cubic crystal structure.

3. The method of claim 1, wherein each of the template region, the p-type semiconductor region, and the n-type emitter region includes a face centered cubic crystal structure.

4. The method of claim 1, wherein the template region includes at least a surface with a biaxially oriented surface texture.

5. The method of claim 1, wherein the template region is electrically conductive and has a face centered cubic crystal structure.

6. The method of claim 1, wherein the template region comprises MgO.

7. The method of claim 6, wherein the n-type emitter region comprises zinc.

8. The method of claim 1, wherein the p-type semiconductor region comprises cuprous oxide and is grown under conditions effective so that the semiconductor region grows epitaxially on the template region.

9. The method of claim 1, wherein the template region is at least one film grown on a support comprising at least one conductive material.

10. The method of claim 1, wherein step (a) comprises using ion beam assisted deposition and/or reactive ion beam assisted deposition to grow at least a portion of the template region such that the template region includes at least a surface having a biaxially oriented texture.

11. The method of claim 1, wherein at least a portion of step (b) occurs in a plasma.

12. The method of claim 1, wherein step (b) occurs under conditions effective to provide biaxially oriented cuprous oxide.

13. (canceled)

14. A method, comprising the steps of:
a) providing a support, wherein at least a portion of the support comprises a template region having a biaxially oriented crystalline structure, said template region having a face;
b) in the presence of a plasma, forming an n-type emitter region on the face of the template region, wherein the n-type emitter region incorporates constituents comprising at least Zn and oxygen; and
c) forming an oriented p-type semiconductor region on the n-type emitter region, wherein the p-type semiconductor region comprises constituents including at least Cu(I) and oxygen;

15. A microelectronic device or precursor thereof comprising,
a) an oriented p-type cuprous oxide semiconductor region;
b) an oriented, monocrystalline n-type emitter region adjacent to the p-type cuprous oxide semiconductor region in a manner such that a p-n heterojunction is formed between the p-type and n-type regions, said n-type region incorporating constituents comprising at least Zn and oxygen; and
c) a region adjacent to at least one of the n-type and p-type regions, wherein at least a portion of the adjacent region has a biaxial crystalline structure and wherein the adjacent region comprises constituents including at least Mg and oxygen.

16. A photovoltaic device, comprising:
a) a substrate including a first electrode and comprising a biaxially oriented, face centered cubic crystal structure and a first lattice constant associated with a preferentially ordered crystalline characteristic of the first electrode;
b) a p-type cuprous oxide semiconductor region disposed on the substrate and having face centered cubic crystal structure and a second lattice constant associated with a preferentially ordered crystalline characteristic of the semiconductor region, wherein the ratio of the first lattice constant to the second lattice constant is in the range from about 1:1.05 to about 1.05:1;
c) a monocrystalline, zinc oxide n-type emitter region adjacent the p-type cuprous oxide semiconductor region and having face centered cubic crystal structure and a third lattice constant associated with a preferentially ordered crystalline characteristic of at least a portion of the n-type emitter region; and
d) a transparent electrode formed directly or indirectly on the n-type emitter region.
